(19) United States
(12) Patent Application Publication
(10) Pub. No.: US 2025/0278120 A1
(43) Pub. Date: Sep. 4, 2025

(54) DISPLAY DEVICE INCLUDING A COVER WINDOW HAVING A PATTERNED PORTION AND A METHOD FOR FABRICATING THE SAME

(71) Applicant: SAMSUNG DISPLAY CO., LTD., Yongin-si (KR)

(72) Inventors: Jin Gyu SIM, Yongin-si (KR); Byung Hoon KANG, Yongin-si (KR); Sang Hoon KIM, Yongin-si (KR); Hyun Ji LEE, Yongin-si (KR); Tae Hyeog JUNG, Yongin-si (KR); Seong Jin HWANG, Yongin-si (KR)

(21) Appl. No.: 18/950,670

(22) Filed: Nov. 18, 2024

(30) Foreign Application Priority Data
Feb. 29, 2024 (KR) 10-2024-0029642

(51) Int. Cl. G06F 1/16

(52) U.S. Cl. CPC G06F 1/1656; G06F 1/1616

(57) ABSTRACT

A display device includes: a display panel including a folding area and a first and second non-folding areas; and a cover window on the display panel and having a patterned portion overlapping the folding area, and including a plurality of first concave grooves and a plurality of second concave grooves, wherein each of the plurality of first and second concave grooves includes an inner wall that extends from a surface of the cover window and a curved surface that extends from the inner wall, wherein an angle formed by the surface of the cover window and the inner wall ranges from about 80 degrees to about 89 degrees, wherein a radius of curvature at an end of the curved surface is greater than about 10 μm and less than about 30 μm, and wherein the patterned portion has a width in a first direction of the cover window.

This application claims priority under 35 U.S.C. § 119 to Korean Patent Application No. 10-2024-0029642, filed on Feb. 29, 2024 in the Korean Intellectual Property Office, the disclosure of which is incorporated by reference herein in its entirety.

### TECHNICAL FIELD

Embodiments of the present invention relate to a display device and a method for fabricating the same, and more particularly, to a display device including a cover window having a patterned portion and a method for fabricating the same.

### DISCUSSION OF THE RELATED ART

As the information-oriented society evolves, various desires of display devices are ever increasing. For example, display devices are being employed by a variety of electronic devices such as smart phones, digital cameras, laptop computers, navigation devices, and smart televisions.

Recently, to increase portability of the display device and provide a wider display screen, a bendable display device, in which the display area can be bent, or a foldable display device, in which the display area can be folded is currently under development.

Regarding the foldable display devices, there is a trend to use patterned glass to ensure impact resistance and flexibility, which are desirable characteristics for foldable display devices.

For example, the patterned glass used has a non-penetrating zigzag pattern. In the process of forming such a pattern, the state in which the foldable display device is folded should be considered, and the pattern should be formed with a consistent arrangement. Currently, the pattern formation on the glass is under development to provide increased impact resistance and increased flexibility, without defects such as abnormal folding and warpage.

### SUMMARY

According to an embodiment of the present invention, a display device includes: a display panel including a folding area, a first non-folding area disposed on a first side of the folding area, and a second non-folding area disposed on second side of the folding area; and a cover window located on the display panel and having a patterned portion formed to overlap the folding area, wherein the patterned portion includes a plurality of first concave grooves and a plurality of second concave grooves, wherein the plurality of first concave grooves are formed in a first surface of the cover window, and the plurality of second concave grooves are formed in a second surface of the cover window that is opposite to the first surface and faces the display panel, wherein each of the plurality of first and second concave grooves includes an inner wall that extends from the first surface or the second surface of the cover window and a curved surface that extends from the inner wall, wherein an angle formed by the first surface of the cover window and the inner wall of the first concave groove ranges from about 80 degrees to about 89 degrees, wherein a radius of curvature at an end of the curved surface of the first concave groove is greater than about 10 μm and less than about 30 μm, and wherein the patterned portion has a width in a first direction of the cover window, wherein the width is calculated by a following equation: L≤π(r+T)+1, wherein r denotes a radius of curvature of the cover window disposed at a position overlapping with the folding area when the display panel is folded, wherein T denotes a thickness of the cover window, and L denotes the width of the patterned portion.

In an embodiment of the present invention, the radius of curvature at the end of the curved surface is smaller than the radius of curvature of the curved surface at a boundary between the inner wall and the curved surface.

In an embodiment of the present invention, the first concave groove further includes a chamfered surface that is disposed between the inner wall of the first concave groove and the first surface of the cover window.

In an embodiment of the present invention, a minimum length of the chamfered surface from the inner wall of the first concave groove to the first surface of the cover window ranges from about 2 μm to 10 μm.

In an embodiment of the present invention, an angle formed by the first surface of the cover window and the chamfered surface is smaller than an angle that is formed by the first surface of the cover window and the inner wall of the first concave groove.

In an embodiment of the present invention, the plurality of first concave grooves and the plurality of second concave grooves have a same shape as each other, wherein the first concave grooves are recessed from the first surface toward the second surface, and wherein the second concave grooves are recessed from the second surface toward the first surface.

In an embodiment of the present invention, the first concave grooves and the second concave grooves are alternately arranged with each other.

In an embodiment of the present invention, each of the first concave grooves and the second concave grooves has a semicircular shape or a polygonal shape.

In an embodiment of the present invention, a number of the first concave grooves is greater than a number of the second concave grooves.

In an embodiment of the present invention, the number of the first concave grooves is odd.

According to an embodiment of the present invention, a display device includes: a display panel including a folding area, a first non-folding area disposed on a first side of the folding area, and a second non-folding area disposed on a second side of the folding area; and a cover window located on the display panel and having a pattern portion overlapping the folding area, wherein the pattern portion includes a plurality of first concave grooves and a plurality of second concave grooves, wherein the plurality of first concave grooves are formed in a first surface of the cover window, and the plurality of second concave grooves are formed in a second surface of the cover window opposite to the first surface and facing the display panel, wherein each of the plurality of first and second concave grooves includes an inner wall that extends from the first surface or the second surface of the cover window, a curved surface that extends from the inner wall, and a chamfered surface located adjacent to the inner wall, wherein an angle formed by the first surface of the cover window and the inner wall of the first concave groove ranges from about 80 degrees to about 89 degrees, and wherein a radius of curvature at an end of the curved surface of the first concave groove is greater than about 10 μm and less than about 30 μm.

In an embodiment of the present invention, a minimum length of the chamfered surface from the inner wall to the first surface of the cover window ranges from about 2 μm to 10 μm.

In an embodiment of the present invention, an angle formed by the first surface of the cover window and the chamfered surface is smaller than an angle that is formed by the first surface of the cover window and the inner wall of the first concave groove.

In an embodiment of the present invention, the radius of curvature at the end of the curved surface is smaller than the radius of curvature of the curved surface at a boundary between the inner wall and the curved surface.

In an embodiment of the present invention, the plurality of first concave grooves and the plurality of second concave grooves have a same shape as each other, wherein the first concave grooves are recessed from the first surface toward the second surface, and wherein the second concave grooves are recessed from the second surface toward the first surface.

In an embodiment of the present invention, the first concave grooves and the second concave grooves are alternately arranged with each other.

In an embodiment of the present invention, a number of the first concave grooves is greater than a number of the second concave grooves.

According to an embodiment of the present invention, a method for fabricating a display device includes: preparing a cover window for protecting a display panel including a folding area, a first non-folding area disposed on a first side of the folding area, and a second non-folding area disposed on a second side of the folding area; and forming a patterned portion in the cover window to overlap with the folding area, wherein the forming of the patterned portion in the cover window includes: forming a plurality of first concave grooves in a first surface of the cover window; and forming a plurality of second concave grooves in a second surface of the cover window that is opposite to the first surface, wherein each of the plurality of first and second concave grooves includes an inner wall that extends from the first surface or the second surface of the cover window and a curved surface that extends from the inner wall, wherein an angle formed by the first surface of the cover window and the inner wall of the first concave groove ranges from about 80 degrees to about 89 degrees, wherein a radius of curvature at an end of the curved surface of the first concave groove is greater than about 10 μm and less than about 30 μm, and wherein the patterned portion has a width in a first direction of the cover window, wherein the width is calculated by a following equation: L≤π(r+T)+1, wherein r denotes a radius of curvature of the cover window disposed at a position overlapping with the folding area when the display panel is folded, wherein T denotes a thickness of the cover window, and L denotes the width of the patterned portion.

In an embodiment of the present invention, the method further includes forming a chamfered surface in each of the first and second concave grooves by chamfering.

In an embodiment of the present invention, the first and second concave grooves are formed by laser-induced deep etching (LIDE).

### BRIEF DESCRIPTION OF THE DRAWINGS

The above and other aspects and features of the present invention will become more apparent by describing in detail embodiments thereof with reference to the attached drawings, in which:

FIG. 1 is a perspective view of a display device according to an embodiment of the present invention when it is unfolded.

FIG. 2 is a perspective view showing the display device of FIG. 1 when it is folded.

FIG. 3 is an exploded perspective view of a display device according to an embodiment of the present invention.

FIG. 4 is a view showing a side of the display device according to an embodiment of the present invention.

FIG. 5 is a cross-sectional view of the display panel of FIGS. 3 and 4.

FIG. 6 is an enlarged cross-sectional view of a patterned portion of FIGS. 3 and 4.

FIG. 7 is an enlarged cross-sectional view of a part of the patterned portion of FIG. 6.

FIG. 8 is an enlarged cross-sectional view of the first and second concave grooves of FIG. 7.

FIG. 9 is a view showing the folding state of the cover glass when it is folded together with the display panel.

FIG. 10 is a view showing stress and strain test results according to the width L of the pattern portion of the cover window.

FIG. 11 is a view showing test results according to the radius of curvature of the concave groove of FIG. 8.

FIG. 12 is a view showing chamfered surfaces formed in the first and second concave grooves of FIG. 8.

FIG. 13 is a view showing the test results of impact resistance of the chamfered surface of FIG. 12.

FIG. 14 is a flowchart for illustrating a method for fabricating a display device according to an embodiment of the present invention.

### DETAILED DESCRIPTION OF THE EMBODIMENTS

The present invention will now be described more fully hereinafter with reference to the accompanying drawings. The present invention may, however, be embodied in different forms and should not be construed as limiting of the present invention. The same reference numbers may indicate the same components throughout the specification and drawings, and thus, repetitive descriptions may be omitted. In the attached figures, various thicknesses, lengths, and angles are shown and while the arrangement shown does indeed represent an embodiment of the present disclosure, it is to be understood that modifications of the various thicknesses, lengths, and angles may be possible within the spirit and scope of the present disclosure and the present disclosure is not necessarily limited to the particular thicknesses, lengths, and angles shown.

It will also be understood that when a layer is referred to as being “on” another layer, it can be directly on the other layer, or intervening layers may also be present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

It will be understood that, although the terms “first,” “second,” etc. may be used herein to describe various elements, these elements should not be limited by these terms. These terms are only used to distinguish one element from another element. For instance, a first element discussed below could be termed a second element without departing from the spirit and scope of the present invention. Similarly, the second element could also be termed the first element.

Features of each of various embodiments of the present invention may be partially or entirely combined with each other and may technically variously interwork with each other, and respective embodiments may be implemented independently of each other or may be implemented together in association with each other.

Hereinafter, embodiments of the present invention will be described with reference to the accompanying drawings.

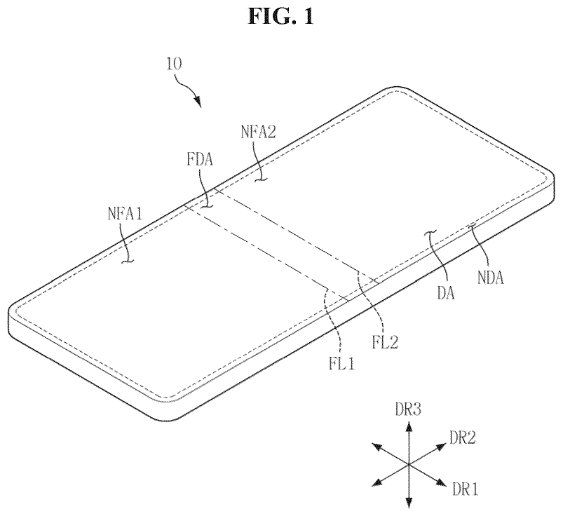

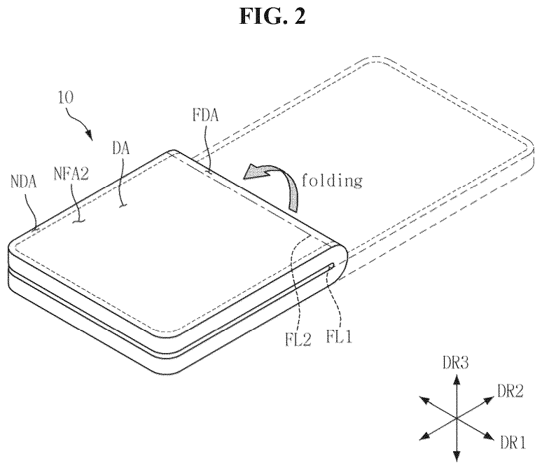

FIG. 1 is a perspective view of a display device according to an embodiment of the present invention when it is unfolded. FIG. 2 is a perspective view showing the display device of FIG. 1 when it is folded.

FIG. 1 shows a first state of the display device 10 when it is not folded along folding lines FL1 and FL2, and FIG. 2 shows a second state of the display device 10 when it is folded along the folding lines FL1 and FL2.

Referring to FIGS. 1 to 2, a display device 10 according to an embodiment of the present invention is for displaying moving images and/or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things (IoT).

Referring to FIGS. 1 and 2, a first direction DR1 may refer to a direction parallel to a side of the display device 10, for example, the horizontal direction of the display device 10 when viewed from the top. A second direction DR2 may refer to a direction parallel to another side of the display device 10 that meets the side of the display device 10, for example, the vertical direction of the display device 10 when viewed from the top. A third direction DR3 may refer to the thickness direction of the display device 10. For example, the first and second directions DR1 and DR2 may extend parallel to a plane of a surface of the display device 10, and the first direction DR1 intersects the second direction DR2. For example, the third direction DR3 is substantially perpendicular to the first and second directions DR1 and DR2.

The display device 10 may have a quadrangular shape, such as a rectangular shape when viewed from the top. Each of the corners of the display device 10 may form a right angle or may be rounded when viewed from the top. The front surface of the display device 10 may include two shorter sides extended in the first direction DR1 and two longer sides extended in the second direction DR2.

The display device 10 includes a display area DA and a non-display area NDA. The shape of the display area DA may follow the shape of the display device 10 when viewed from the top. For example, when the display device 10 has a rectangular shape when viewed from the top, the display area DA may also have a rectangular shape when viewed from the top.

The display area DA may include a plurality of pixels to display images. The non-display area NDA might not include pixels and thus might not display images. The non-display area NDA may be disposed around the display area DA. The non-display area NDA may surround the display area DA, but embodiments of the present invention is not limited thereto. For example, the display area DA may be partially surrounded by the non-display area NDA.

The display device 10 is configured to be in a first state, which is an unfolded state, or a second state, which isa bent or folded state. The display device 10 may be folded inward so that a first part of the display area DA faces a second part of the display area DA. For example, the display device 10 may be folded in an in-folding manner, as shown in FIG. 2. In this instance, a part of the front surface of the display device 10 may face another part of the display device 10 when the display device 10 is folded. In addition, the display device 10 may be folded outward (e.g., an out-folding manner) such that a part of the rear surface of the display device 10 faces another part of the rear surface of the display device 10 when it is folded.

The display device 10 may include a folding area FDA, a first non-folding area NFA1, and a second non-folding area NFA2. The display device 10 can be bent or folded at the folding area FDA, while it cannot be bent or folded at the first non-folding area NFA1 and the second non-folding area NFA2. That is to say, the first non-folding area NFA1 and the second non-folding area NFA2 may be flat areas of the display device 10.

The first non-folding area NFA1 may be disposed at a first side of the folding area FDA. For example, the first non-folding area NFA1 may be disposed at the lower side of the folding area FDA. The second non-folding area NFA2 may be disposed at a second side, opposite to the first side, of the folding area FDA. For example, the second non-folding area NFA2 may be disposed at the upper side of the folding area FDA. The folding area FDA may be defined by the first folding line FL1 and the second folding line FL2, where the display device 10 can be bent with a predetermined curvature. The first folding line FL1 may be the boundary between the folding area FDA and the first non-folding area NFA1, and the second folding line FL2 may be the boundary between the folding area FDA and the second non-folding area NFA2.

Each of the display area DA and the non-display area NDA may overlap at least one of the folding area FDA, the first non-folding area NFA1, or the second non-folding area NFA2. In the example shown in FIGS. 1 and 2, each of the display area DA and the non-display area NDA overlaps the folding area FDA, the first non-folding area NFA1 and the second non-folding area NFA2.

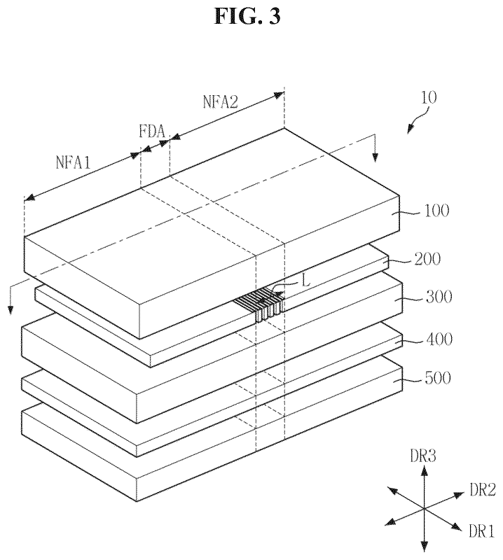

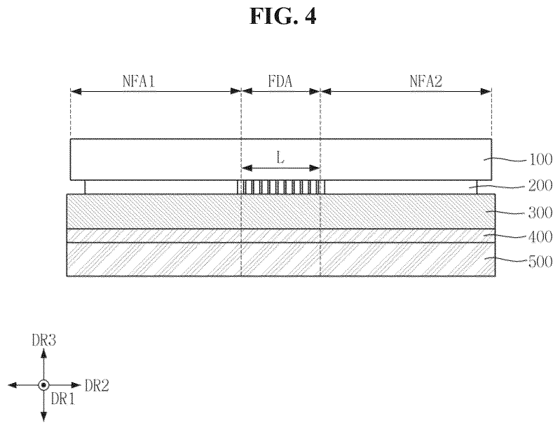

FIG. 3 is an exploded perspective view showing a display device according to an embodiment of the present invention. FIG. 4 is a view showing a side of the display device according to the embodiment of the present invention.

Referring to FIGS. 3 and 4, a display device 10 according to an embodiment of the present invention may include an upper protection member 100, a cover window 200, a first adhesive member 300, a display panel 400, and a panel protection member 500.

The upper protection member 100 may be disposed on the front surface of the cover window 200. The upper protection member 100 may be attached on the front surface of the cover window 200. The upper protection member 100 may perform at least one of an anti-scattering function when the cover window 200 is broken, a shock absorption function, an anti-scratch function, an anti-fingerprint function, or an anti-glare function.

A light-blocking pattern may be formed on the rear surface of the upper protection member 100. The light-blocking pattern may be disposed at or adjacent to the edge of the upper protection member 100. The light-blocking pattern may include a light-blocking material that can block light. For example, the light-blocking pattern may be an inorganic black pigment such as carbon black, organic black pigment, or an opaque metallic substance

The cover window 200 may be attached on the front surface of the display panel 400 by the first adhesive member 300. The cover window 200 may be made of a transparent material, and may be, for example, glass or plastic. For example, the cover window 200 may be, but is not limited to, an ultra-thin glass (UTG) having a thickness of about 0.1 mm or less or a transparent polyimide film.

The first adhesive member 300 may be located between the cover window 200 and the display panel 400 to attach the cover window 200 to the display panel 400, and may be a transparent adhesive film or a transparent adhesive resin.

The display panel 400 may be a panel for displaying images. The display panel 400 may be, for example, an organic light-emitting display panel including an organic light-emitting layer, a quantum-dot light-emitting display panel including a quantum-dot light-emitting layer, an inorganic light-emitting display panel using inorganic semiconductor elements as the light-emitting elements, and a micro light-emitting display panel using micro light-emitting diodes as the light-emitting elements. In the following description, as an example, an organic light-emitting display panel is employed as the display panel 400. It is, however, to be understood that the present invention is not limited thereto.

The panel protection member 500 may be disposed on the rear surface of the display panel 400. The panel protection member 500 can support the display panel 400 and protect the rear surface of the display panel 400. The panel protection member 500 may be made of plastic such as polyethylene terephthalate and polyimide, or glass. Although the panel protection member 500 is disposed in the folding area FDA of the display device 10 in the example of FIGS. 3 and 4, the embodiments of the present invention are not limited thereto. For example, the panel protection film 500 may be removed from the folding area FDA of the display device 10 so that the display device 10 can be folded smoothly.

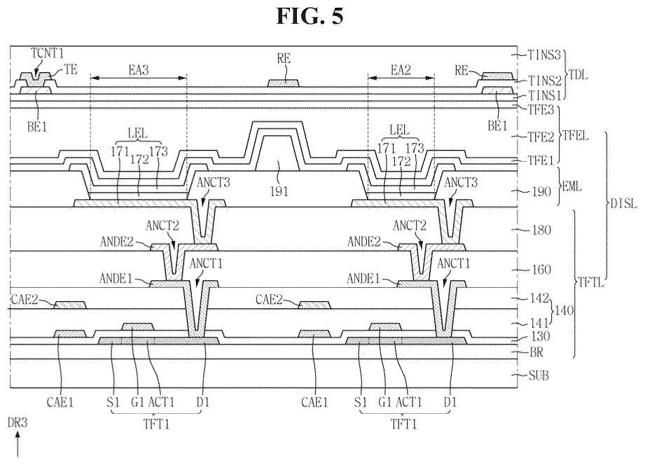

FIG. 5 is a cross-sectional view of the display panel of FIGS. 3 and 4.

Referring to FIG. 5, in the display panel 400, a display layer DISL may be disposed on a substrate SUB.

The display layer DISL may include a thin-film transistor layer TFTL, an emission material layer EML, and an encapsulation layer TFEL.

The thin-film transistor layer TFTL may be disposed on the substrate SUB. The thin-film transistor layer TFTL may include a barrier layer BR, a thin-film transistor TFT1, a first capacitor electrode CAE1, a second capacitor electrode CAE2, a first anode connection electrode ANDE1, a second anode connection electrode ANDE2, a gate insulator 130, a first interlayer dielectric film 141, a second interlayer dielectric film 142, a first planarization film 160, a second planarization film 180.

The substrate SUB may be made of an insulating material such as a polymer resin. For example, the substrate SUB may be made of polyimide. The substrate SUB may be a flexible substrate that can be bent, folded, or rolled.

The barrier film BR may be disposed on the substrate SUB. The barrier film BR is a film for protecting the thin-film transistors of the thin-film transistor layer TFTL and an emissive layer 172 of the emission material layer EML. The barrier film BR may be made up of multiple inorganic films stacked on one another. For example, the barrier film BR may be made up of multiple layers in which one or more inorganic layers of a silicon nitride layer, a silicon oxynitride layer, a silicon oxide layer, a titanium oxide layer and an aluminum oxide layer are alternately stacked on one another.

The thin-film transistors TFT1 may be disposed on the barrier film BR.

An active layer ACT1 of the thin-film transistor TFT1 may be disposed on the barrier layer BR. The active layer ACT1 of the thin-film transistor TFT1 may include, for example, polycrystalline silicon, monocrystalline silicon, low-temperature polycrystalline silicon, amorphous silicon, or an oxide semiconductor.

The active layer ACT1 may include a channel region CHA1, a source region S1 and a drain region D1. The channel region CHA1 may overlap with a gate electrode G1 in the third direction DR3, for example, the thickness direction of the substrate SUB. The source region S1 may be disposed on one side of the channel region CHA1, and the drain region D1 may be disposed on the opposite side of the channel region CHA1. The source region S1 and the drain region D1 might not overlap with the gate electrode G1 in the third direction DR3. The source region S1 and the drain region D1 may be formed by doping a silicon semiconductor or an oxide semiconductor with ions or impurities to have conductivity.

The gate insulator 130 may be disposed on the active layer ACT1 of the thin-film transistor TFT1. The gate insulator 130 may be formed of an inorganic layer, for example, a silicon nitride layer, a silicon oxynitride layer, a silicon oxide layer, a titanium oxide layer, or an aluminum oxide layer.

The gate electrode G1 and the first capacitor electrode CAE1 of the thin-film transistor TFT1 may be disposed on the gate insulator 130. The gate electrode G1 may overlap with the active layer ACT1 in the third direction DR3. Although the gate electrode G1 and the first capacitor electrode CAE1 are spaced apart from each other in the example shown in FIG. 5, the gate electrode G1 and the first capacitor electrode CAE1 may be connected with each other as a single piece. For example, the gate electrode G1 and the first capacitor electrode CAE1 may be an integrated layer. The gate electrode G1 and the first capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 141 may be disposed on the gate electrode G1 of the thin-film transistor TFT1 and the first capacitor electrode CAE1. The first interlayer dielectric film 141 may be formed of an inorganic layer, for example, a silicon nitride layer, a silicon oxynitride layer, a silicon oxide layer, a titanium oxide layer, or an aluminum oxide layer. The first interlayer dielectric film 141 may be made of a plurality of inorganic films. However, the present invention is not limited thereto.

The second capacitor electrode CAE2 may be disposed on the first interlayer dielectric layer 141. The second capacitor electrode CAE2 may overlap the first capacitor electrode CAE1 of the thin-film transistor TFT1 in the third direction DR3. In addition, when the gate electrode G1 and the first capacitor electrode CAE1 are formed as a single piece, the second capacitor electrode CAE2 may overlap the gate electrode G1 in the third direction DR3. Since the first interlayer dielectric layer 141 has a predetermined dielectric constant, a capacitor can be formed by the first capacitor electrode CAE1, the second capacitor electrode CAE2 and the first interlayer dielectric layer 141 disposed therebetween. The second capacitor electrode CAE2 may be made up of a single layer or multiple layers of one of, for example, molybdenum (Mo), aluminum (Al), chromium (Cr), gold (Au), titanium (Ti), nickel (Ni), neodymium (Nd) and copper (Cu) or an alloy thereof.

A second interlayer dielectric layer 142 may be disposed over the second capacitor electrode CAE2. The second interlayer dielectric film 142 may be formed of an inorganic layer, for example, a silicon nitride layer, a silicon oxynitride layer, a silicon oxide layer, a titanium oxide layer, or an aluminum oxide layer. The second interlayer dielectric film 142 may be made of a plurality of inorganic films. However, the present invention is not limited thereto.

A first anode connection electrode ANDE1 may be disposed on the second interlayer dielectric layer 142. The first anode connection electrode ANDE1 may be connected to the drain electrode D1 of the thin-film transistor TFT1 through a first connection contact hole ANCT1 that penetrates the gate insulator 130, the first interlayer dielectric film 141 and the second interlayer dielectric film 142. The first anode connection electrode ANDE1 may be made up of a single layer or multiple layers of one of, for example, molybdenum (Mo), aluminum (Al), chromium (Cr), gold (Au), titanium (Ti), nickel (Ni), neodymium (Nd) and copper (Cu) or an alloy thereof.

A first planarization film 160 may be disposed over the first anode connection electrode ANDE1 and may provide a flat surface over level differences that are formed from the thin-film transistor TFT1. The first planarization film 160 may be formed of an organic layer such as an acryl resin, an epoxy resin, a phenolic resin, a polyamide resin and a polyimide resin.

A second anode connection electrode ANDE2 may be disposed on the first planarization layer 160. The second anode connection electrode ANDE2 may be connected to the first anode connection electrode ANDE1 through a second connection contact hole ANCT2 that penetrates the first planarization layer 160. The second anode connection electrode ANDE2 may be made up of a single layer or multiple layers of one of, for example, molybdenum (Mo), aluminum (Al), chromium (Cr), gold (Au), titanium (Ti), nickel (Ni), neodymium (Nd) and copper (Cu) or an alloy thereof.

A second planarization film 180 may be disposed on the second anode connection electrode ANDE2. The second planarization film 180 may be formed as an organic layer such as an acryl resin, an epoxy resin, a phenolic resin, a polyamide resin and a polyimide resin.

An emission material layer EML including light-emitting elements LEL and a bank 190 may be disposed on the second planarization film 180. Each of the light-emitting elements LEL includes a pixel electrode 171, an emissive layer 172, and a common electrode 173.

The pixel electrode 171 may be disposed on the second planarization film 180. The pixel electrode 171 may be connected to the second anode connection electrode ANDE2 through a third connection contact hole ANCT3 that penetrates the second planarization film 180.

In the top-emission structure in which light exits from the emissive layer 172 toward the common electrode 173, the pixel electrode 171 may be made of a metal material having a high reflectivity such as a stack structure of aluminum and titanium (Ti/Al/Ti), a stack structure of aluminum (Al) and ITO (Indium Tin Oxide) (ITO/Al/ITO), an APC alloy and a stack structure of an APC alloy and ITO (ITO/APC/ITO). The APC alloy is an alloy of silver (Ag), palladium (Pd) and copper (Cu).

To define the first emission area, the second emission area EA2, the third emission area EA3 and the fourth emission area, the bank 190 may be formed to partition the pixel electrode 171 on the second planarization film 180. The bank 190 may be disposed to cover the edges of the pixel electrode 171. The bank 190 may be formed of an organic layer such as an acryl resin, an epoxy resin, a phenolic resin, a polyamide resin and a polyimide resin.

In each of the first emission area, the second emission area EA2, the third emission area EA3 and the fourth emission area, the pixel electrode 171, the emissive layer 172 and the common electrode 173 are stacked on one another sequentially, so that holes from the pixel electrode 171 and electrons from the common electrode 173 are recombined with each other in the emissive layer 172 to emit light.

The emissive layer 172 may be disposed on the pixel electrode 171 and the bank 190. The emissive layer 172 may include an organic material to emit light of a certain color. For example, the emissive layer 172 may include a hole transporting layer, an organic material layer, and an electron transporting layer.

The common electrode 173 may be disposed on the emissive layer 172 and the bank 190. The common electrode 173 may be disposed to cover the emissive layer 172. The common electrode 173 may be a common layer that is formed commonly in the first emission area, the second emission area EA2, the third emission area EA3 and the fourth emission area. A capping layer may be formed on the common electrode 173.

In the top-emission organic light-emitting diode, the common electrode 173 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is formed of a semi-transmissive metal material, the light extraction efficiency can be increased by using microcavities.

A spacer 191 may be disposed on the bank 190. The spacer 191 may support a mask during a process of fabricating the emissive layer 172. The spacer 191 may be formed of an organic layer such as an acryl resin, an epoxy resin, a phenolic resin, a polyamide resin and a polyimide resin.

An encapsulation layer TFEL may be disposed on the common electrode 173. The encapsulation layer TFEL includes at least one inorganic film to prevent permeation of oxygen or moisture into the emission material layer EML. In addition, the encapsulation layer TFEL includes at least one organic layer to protect the light-emitting element layer EML from foreign substances such as dust. For example, the encapsulation layer TFEL includes a first inorganic encapsulation film TFE1, an organic encapsulation film TFE2 and a second inorganic encapsulation layer TFE3.

The first inorganic encapsulation film TFE1 may be disposed on the common electrode 173. The organic encapsulation film TFE2 may be disposed on the first inorganic encapsulation film TFE1, and the second inorganic encapsulation film TFE3 may be disposed on the organic encapsulation film TFE2. For example, the first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

A touch detecting layer TDL may be disposed on the encapsulation layer TFEL. The touch detecting layer TDL includes a first touch insulating film TINS1, connection electrodes BE, a second touch insulating film TINS2, the driving electrodes TE, the sensing electrodes RE, and a third touch insulating film TINS3.

The first touch insulating film TINS1 may be disposed on the encapsulation layer TFEL. The first touch insulating film TINS1 may be formed of an inorganic layer, for example, a silicon nitride layer, a silicon oxynitride layer, a silicon oxide layer, a titanium oxide layer, or an aluminum oxide layer.

The connection electrode BE1 may be disposed on the first touch insulating film TINS1. The connection electrode BE1 may be made up of a single layer or multiple layers of one of, for example, molybdenum (Mo), aluminum (Al), chromium (Cr), gold (Au), titanium (Ti), nickel (Ni), neodymium (Nd) and copper (Cu) or an alloy thereof.

The second touch insulating film TINS2 is disposed over the connection electrodes BE1. The second touch insulating layer TINS2 may be formed of an inorganic layer, for example, a silicon nitride layer, a silicon oxynitride layer, a silicon oxide layer, a titanium oxide layer, or an aluminum oxide layer. In addition, the second touch insulating layer TINS2 may be formed of an organic layer such as an acryl resin, an epoxy resin, a phenolic resin, a polyamide resin and a polyimide resin.

The driving electrodes TE and the sensing electrodes RE may be disposed on the second touch insulating film TINS2. In addition to the driving electrodes TE and the sensing electrodes RE, the dummy patterns DE, the first touch driving lines, the second touch driving lines and the touch sensing lines may be disposed on the second touch insulating film TINS1. The driving electrodes TE and the sensing electrodes RE may be made up of a single layer or multiple layers of one of, for example, molybdenum (Mo), aluminum (Al), chromium (Cr), gold (Au), titanium (Ti), nickel (Ni), neodymium (Nd) and copper (Cu) or an alloy thereof.

The driving electrodes TE and the sensing electrodes RE may overlap with the connection electrodes BE1 in the third direction DR3. The driving electrodes TE may be connected to the connection electrodes BE1 through touch contact holes TCNT1 that penetrate through the first touch insulating film TINS1.

The third touch insulating film TINS3 is formed over the driving electrodes TE and the sensing electrodes RE. The third touch insulating layer TINS3 may provide a flat surface over the driving electrodes TE, the sensing electrodes RE and the connection electrodes BE1 which having different heights. The third touch insulating film TINS3 may be formed of an organic layer such as an acryl resin, an epoxy resin, a phenolic resin, a polyamide resin and a polyimide resin.

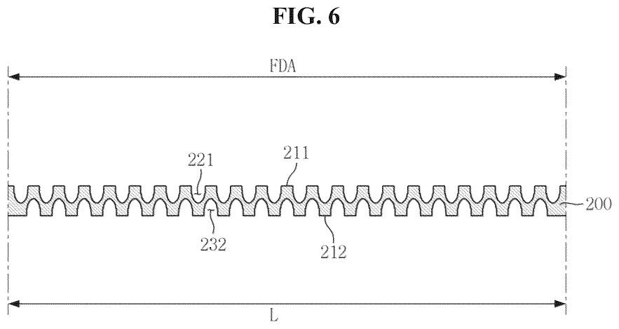

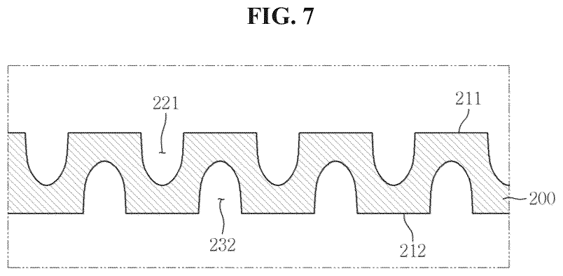

FIG. 6 is an enlarged cross-sectional view of a patterned portion of FIGS. 3 and 4. FIG. 7 is an enlarged cross-sectional view of a part of the patterned portion of FIG. 6.

Referring to FIG. 6, the cover window 200 may include an upper surface 211, which is a first surface facing the upper protection member 100 of FIG. 3, and a lower surface 212, which is a second surface facing the display panel 400 having the first adhesive member 300 attached thereto as the opposite surface to the upper surface 211.

The cover window 200 may include the patterned portion 221 and 232 formed in the folding area FDA.

The patterned portion 221 and 232 may be formed in a part of the cover window 200 in the horizontal direction that has a width L that is substantially equal to the width of the folding area FDA. For example, the patterned portion 221 and 232 formed only in a part of the cover window 200 in FIGS. 3 and 4 may have the width L.

The patterned portion 221 and 232 may include a plurality of first concave grooves 221 and a plurality of second concave grooves 232, and the plurality of first concave grooves 221 and the plurality of second concave grooves 232 disposed in the folding area FDA.

The first concave grooves 221 may be formed in the upper surface 211 of the cover window 200, and the first concave grooves 221 may be spaced apart from one another along the horizontal direction, which is the surface direction of the upper surface 211.

For example, an odd number of first concave grooves 221 may be formed for symmetry when the cover window 200 is folded. The number of the first concave grooves 221 may be greater than the number of the second concave grooves 232.

The second concave grooves 232 may be formed in the lower surface 212 of the cover window 200, and the second concave grooves 232 may be spaced apart from one another along the horizontal direction, which is the surface direction of the upper surface 212. For example, the number of the second concave grooves 232 may be smaller than the number of the first concave grooves 221. However, the present invention is not limited thereto. For example, the number of the second concave grooves 232 may be larger than the number of the first concave grooves 221.

The first concave grooves 221 and the second concave grooves 232 may be arranged alternately so that they do not overlap each other.

Referring to FIG. 7, each of the first concave grooves 221 may be located in the upper surface 211 of the cover window 200 and may include a concave groove shape that is recessed toward the lower surface 212.

Each of the second concave grooves 232 may be located in the lower surface 212 of the cover window 200 and may include a concave groove shape that is recessed toward the upper surface 212.

The first concave grooves 221 may have, but is not limited to, a semicircular cross-sectional shape or a polygonal cross-sectional shape. They may be formed in a variety of shapes.

The second concave grooves 232 may have, but is not limited to, a semicircular cross-sectional shape or a polygonal cross-sectional shape, like the first concave grooves 221. The second concave grooves 232 may be arranged alternately with the first concave grooves 221 and may have a different shape from that of the first concave grooves 221. However, the present invention is not limited thereto. For example, the second concave grooves 232 may be alternately arranged with different shapes from each other.

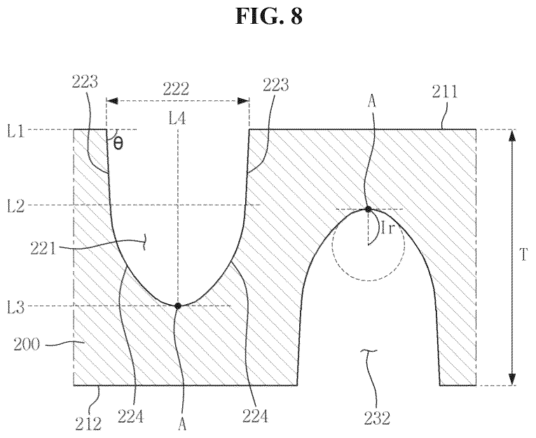

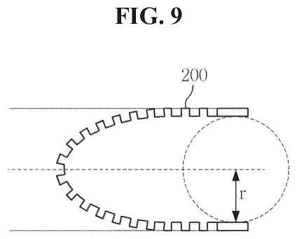

FIG. 8 is an enlarged cross-sectional view of the first and second concave grooves of FIG. 7. FIG. 9 is a view showing the folding state of the cover glass when it is folded together with the display panel.

Referring to FIG. 8, since the first concave grooves 221 and the second concave grooves 232 have the same shape and the same configuration as each other, except for being formed in different surfaces of the cover window 200, the following description will be made based on the first concave grooves 221.

The first concave groove 221 may be formed in the upper surface 211 of the cover window 200. The first concave groove 221 may include inner walls 223, curved surfaces 224, and an opening 222. The inner walls 223 may extend from the upper surface 211 of the cover window 200. The curved surfaces 224 may extend from the inner walls 223, and the opening 222 may expose the curved surfaces 224 on the opposite side of the curved surfaces 224.

The inner walls 223 refer to the both inner side surfaces that are located in the internal space of the first concave groove 221 and may be located between a first line L1 and a second line L2, which are straight lines in a cross section.

The curved surfaces 224 may be internal bottom surfaces that are located in the internal space of the first concave groove 221, and may have a semicircular shape forming a curve in a cross section.

For example, the curved surfaces 224 may be in the form of a parabola having a vertex where a third line L3, which is the horizontal line passing through the end (e.g., the lowest point) of the first concave groove 221, and a fourth line L4, which is a vertical line, intersect each other. For example, the fourth line L4 is a vertical line that extends through a center of the first concave groove 221.

An angle θ formed by the inner wall 223 of the first concave groove and the upper surface 211 of the cover window 200 may range from about 80 degrees to about 89 degrees.

For example, the angle θ formed by the first line L1, which is a straight line extending parallel to the upper surface 211 of the cover window 200, and the inner wall 223 may range from about 80 degrees to about 89 degrees, for example, about 84 degrees to about 88 degrees.

The first concave groove 221 may have a curvature radius Ir that is greater than about 10 μm and less than about 30 μm. For example, the first concave groove 221 may have a curvature radius Ir that is about 20 μm at a vertex A, which is the end of the first concave groove 221.

The curvature radius Ir at the vertex A of the first concave groove 221 may be smaller than the radius of curvature at the boundary between the inner wall 223 and the curved surface 224 of the first concave groove 221.

That is to say, in the first concave groove 221, the curvature radius Ir of a circle drawn at the vertex A may be smaller than the radius of curvature of a circle drawn with the center at the intersection point where the second line L2 and the fourth line LA intersect each other.

Herein, the second concave groove 232 is identical to the above-described first concave groove 221, and the angle θ and the radius of curvature Ir of the second concave groove 232 may be equal to those of the first concave groove 221.

In the patterned portion 221 and 232 including the first concave groove 221 and the second concave groove 232 as described above, the width L of the patterned portion shown in FIGS. 3, 4 and 6 may satisfy the mathematical expression that is below. That is to say, the width L of the patterned portion can be formed in a numerical range that satisfies the mathematical expression below:

L≤(r+T)+1 [Mathematical Expression]

where r denotes the radius of curvature (r) of the cover window 200 that is folded together with the display panel 400, which is the curvature radius (r) of the cover window shown in FIG. 9. T denotes the thickness of the cover window 200, and L denotes the width of the patterned portion 221 and 232 including the plurality of first and second concave grooves 221 and 232.

As an example, the radius of curvature r of the cover window in FIG. 9 is 1.19 mm, and the thickness T of the cover window in FIG. 8 is 150 μm or 0.15 mm. By inputting the values to the mathematical expression, the calculated value of L is 5.20 mm. The value was calculated to two decimal places.

When the calculated width L of the patterned portion 221 and 232 is 5.20 mm, to form the patterned portion 221 and 232 including a plurality of first and second concave grooves 221 and 232, the patterned portion 221 and 232 may be formed with the width of 5.20 mm at a central part of the cover window 200 in the horizontal direction shown in FIGS. 3 and 4. That is to say, a plurality of first and second concave grooves 221 and 232 may be formed along the horizontal direction as wide as the L value of 5.20 mm.

The L value, which is the width of the patterned portion, may be greater than about 4 mm and smaller than about 5.5 mm, For example, the L value may be about 5.2 mm.

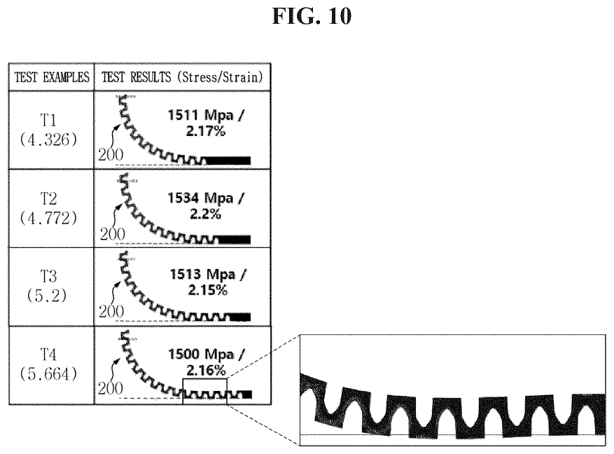

FIG. 10 is a view showing stress and strain test results according to the width L of the patterned portion of the cover window.

Referring to FIG. 10, results of tests T1 to T4 are shown. For tests T1 to T3, if the width L is greater than about 4 mm and less than about 5.5 mm, the patterned portion can be normally folded without deviating from the dotted line, which is the reference line, that is, without reverse bending that deviates from the dotted line. In addition, it can be seen that the stress and strain values do not increase significantly.

However, when the width L exceeds about 5.3 mm, i.e., in test T4, while the stress value is lower than in tests T1 to T3, reverse bending beyond the dotted line occurs as shown in FIG. 10. It can be seen from FIG. 10 that the stress and strain values do not increase significantly while the patterned portion can be folded normally and most stably when the L value is 5.2 mm in test T3.

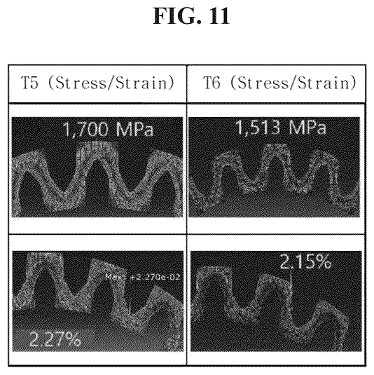

FIG. 11 is a view showing test results according to the radius of curvature Ir of the concave groove of FIG. 8.

Referring to FIG. 11, results of testing the stress and strain in test T5 with the radius of curvature Ir of about 10 μm and test T6 with the radius of curvature Ir of about 20 μm are shown. It can be seen from FIG. 11 that the patterned portion can be normally folded in tests T5 and T6 even when stress is applied if a normal pattern is formed. It should be noted that in test T6 where the radius of curvature is about 20 μm greater than about 10 μm, it can be seen that the stress and strain values greatly decrease. In view of the above, it can be seen that the most desirable value of the radius of curvature of the concave groove Ir is about 20 μm.

As described above, to form the first and second concave grooves 221 and 232, the angle θ of the groove is formed from about 84 degrees to about 88 degrees, the radius of curvature Ir of the concave groove is greater than about 10 μm and less than about 20 μm, and the patterned portion 221 and 232 including the first and second concave grooves 221 and 232 have the width L that satisfies the mathematical expression L≤(r+T)+1. By doing so, the patterned portion of the cover window 200 can be folded normally so that it is horizontally symmetrical as shown in FIG. 9, and the impact resistance can be increased and increased flexibility can be provided, which are desirable characteristics for the foldable display device 10 as shown in FIGS. 10 and 11.

In addition, to increase the impact resistance and provide the flexibility of the foldable display device 10, the width L of the patterned portion 221 and 232 is determined based on the mathematical expression, so that it is possible to prevent defects such as buckling as well as increasing impact resistance and providing excellent flexibility, which are desirable characteristics for foldable display devices.

In addition, it is possible to provide repeatability that allows the patterns of the first and second concave grooves 221 and 232 to be formed consistently and repeatedly at constant intervals.

If the radius of curvature r of the cover window is set but the width L of the patterned portion is not set by the mathematical expression, reverse bending may occur that deviates from the dotted line, which is the reference line, as in test T4 of FIG. 10. As a result, the cover window 200 may be damaged.

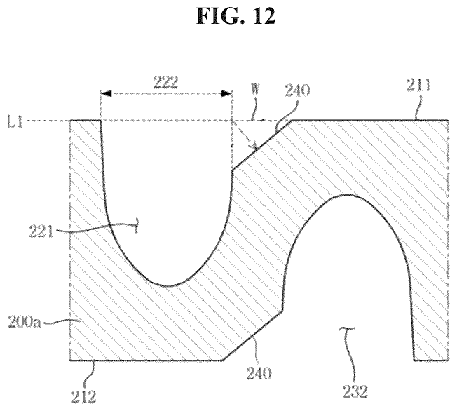

FIG. 12 is a view showing chamfered surfaces formed in the first and second concave grooves of FIG. 8.

Referring to FIG. 12, a cover window 200a according to an embodiment of the present invention may include chamfered surfaces between inner walls 223 of the first and second concave grooves 221 and 232 and the upper surface 211 of the cover window 200. The cover window 200a according to this embodiment is substantially identical to the cover window 200 of FIG. 8 except for the chamfered surfaces 420, and, therefore, the redundant descriptions will be omitted or briefly discussed.

The chamfered surface 240 may be formed by chamfering a corner of the cover window 200a in the direction of the arrow.

The minimum length of the chamfered surface 240 from the inner wall of the first concave groove 221 to the upper surface 211 of the cover window 200 may range from about 2 μm to about 10 μm. For example, in a triangle formed by dotted lines with the chamfer surface 240 as the base, the length W of the both isosceles sides may range from about 2 μm to 10 μm.

By forming the chamfer surface 240, stress is concentrated in the corner area generated when the first and second concave grooves 221 and 232 are formed, thereby preventing the risk of breakage and increasing rigidity.

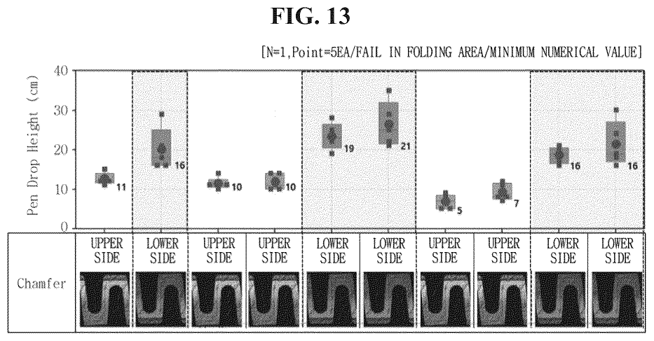

FIG. 13 is a view showing the test results of impact resistance of the chamfered surface of FIG. 12.

Referring to FIG. 13, a chamfered surface 240 was formed adjacent to first and second concave grooves 221 and 232, and then, a pen drop test was conducted for testing impact resistance. It can be seen that when the chamfered surface 240 is formed on both the upper surface 211 and the lower surface 212 of the cover window 200a, the impact resistance performance is increased. For example, when the chamfered surface 240 is formed in the lower surface 212, it was checked that breakage occurs only when the pen is dropped from a height of up to about 16 cm, 19 cm, and 21 cm. In view of the above, it can be seen that the impact resistance is increased when the chamfer surface 240 is formed in the lower surface 212 than when the chamfered surface 240 is formed in the upper surface 211.

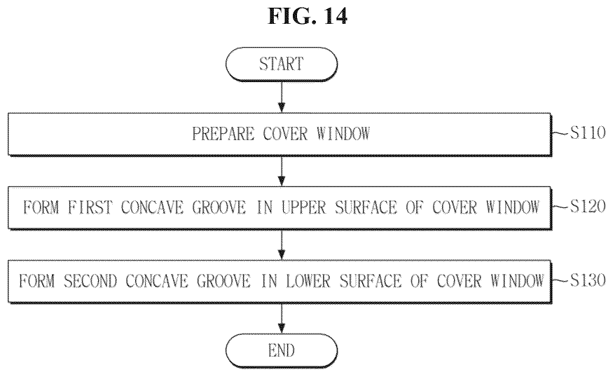

Hereinafter, a method for fabricating a display device according to an embodiment of the present invention will be described with reference to FIG. 14.

FIG. 14 is a flowchart for illustrating a method for fabricating a display device according to an embodiment of the present invention.

First, the method may include preparing a cover window 200 to protect a display panel 400 (step S110 in FIG. 14).

The preparing the cover window 200 may include disposing a cover window on the display panel 400 including a folding area FDA, a first non-folding area NFA1 disposed on one side of the folding area FDA and a second non-folding area NFA2 on the opposite side of the folding area FDA.

In doing so, the width L of the patterned portion 221 and 232 of the cover window 200 may be located in line with the folding area FDA.

Second, the method may include forming first concave grooves 221 in an upper surface 211 of the cover window 200 (step S120 in FIG. 14).

In doing so, a plurality of first concave grooves 221 may be formed with a semicircular cross-sectional shape along the surface direction of the upper surface 211 of the cover window 200. For example, an odd number of first concave grooves 221 may be formed, and the number of first concave grooves 221 may be greater than that of the plurality of second concave grooves 232.

Third, the method may include forming a plurality of second concave grooves 232 in a lower surface 212 of the cover window 200 (step S130 in FIG. 14).

In doing so, a plurality of second concave grooves 232 may be formed with a semicircular cross-sectional shape along the surface direction of the lower surface 212 of the cover window 200, and the first concave grooves 221 and the second concave grooves 232 may be alternately arranged with each other. For example, the number of the second concave grooves 232 may be less than the number of the first concave grooves 221 by one.

The order of forming the first and second concave grooves 221 and 232 is not limited to steps S120 and S130. The second concave grooves 232 may be formed first, and then, the first concave grooves 221 may be formed.

In steps S120 and 130, the first and second concave grooves 221 and 232 may be commonly formed by using a laser-induced deep etching (LIDE).

As a method of forming concave grooves such as the first and second concave grooves 221 and 232, the LIDE may include irradiating the cover window 200 with laser and etching the irradiated area. The etching step may be wet etching as chemical etching.

In addition, in steps S120 and 130, to form the first and second concave grooves 221 and 232, the angle θ of the grooves may be formed from about 84 degrees to about 88 degrees, the radius of curvature Ir of the concave grooves may be greater than about 10 μm and less than about 20 μm, and the patterned portion 221 and 232 including the first and second concave grooves 221 and 232 may have the width L that satisfies the mathematical expression L≤π(r+T)+1.

The method may further include forming a chamfered surface 240 subsequent to steps S120 and S130.

The chamfered surface 240 may be formed by cutting off a corner area of the cover window 200a to a length W that is about 2 μm to 10 μm in an opening 222 of the cover window 200a.

As described above, to form the first and second concave grooves 221 and 232, the angle θ of the groove is formed from about 84 degrees to about 88 degrees, the radius of curvature Ir of the concave groove is greater than about 10 μm and less than about 20 μm, and the patterned portion 221 and 232 including the first and second concave grooves 221 and 232 have the width L that satisfies the mathematical expression L≤(r+T)+1. In doing so, the L value is formed greater than about 4 mm and less than about 5.5 mm, and the chamfered surface has a size of about 2 μm to 10 μm, for example, so that the impact resistance can be increased and increased flexibility can be provided, which are desirable characteristics for the foldable display devices.

In addition, by providing increased flexibility when the device is folded, it is possible to suppress abnormal folding, reverse bending, etc., and, accordingly, to prevent defects such as damage to the cover window.

In addition, the same pattern can be repeatedly formed with a constant interval by using the reference value as described above, so that it is possible to provide repeatability in pattern formation.

While the present invention has been described with reference to the embodiments thereof, it will be understood by those of ordinary skill in the art that various changes in form and detail may be made thereto without departing from the spirit and scope of the present invention.

What is claimed is:

1. A display device comprising:
a display panel comprising a folding area, a first non-folding area disposed on a first side of the folding area, and a second non-folding area disposed on second side of the folding area; and
a cover window located on the display panel and having a patterned portion formed to overlap the folding area,
wherein the patterned portion comprises a plurality of first concave grooves and a plurality of second concave grooves, wherein the plurality of first concave grooves are formed in a first surface of the cover window, and the plurality of second concave grooves are formed in a second surface of the cover window that is opposite to the first surface and faces the display panel,
wherein each of the plurality of first and second concave grooves comprises an inner wall that extends from the first surface or the second surface of the cover window and a curved surface that extends from the inner wall,
wherein an angle formed by the first surface of the cover window and the inner wall of the first concave groove ranges from about 80 degrees to about 89 degrees,
wherein a radius of curvature at an end of the curved surface of the first concave groove is greater than about 10 μm and less than about 30 μm, and
wherein the patterned portion has a width in a first direction of the cover window, wherein the width is calculated by a following equation:
L≤(r+T)+1,
wherein r denotes a radius of curvature of the cover window disposed at a position overlapping with the folding area when the display panel is folded, wherein T denotes a thickness of the cover window, and L denotes the width of the patterned portion.

2. The display device of claim 1, wherein the radius of curvature at the end of the curved surface is smaller than the radius of curvature of the curved surface at a boundary between the inner wall and the curved surface.

3. The display device of claim 2, wherein the first concave groove further comprises a chamfered surface that is disposed between the inner wall of the first concave groove and the first surface of the cover window.

4. The display device of claim 3, wherein a minimum length of the chamfered surface from the inner wall of the first concave groove to the first surface of the cover window ranges from about 2 μm to 10 μm.

5. The display device of claim 4, wherein an angle formed by the first surface of the cover window and the chamfered surface is smaller than an angle that is formed by the first surface of the cover window and the inner wall of the first concave groove.

6. The display device of claim 5, wherein the plurality of first concave grooves and the plurality of second concave grooves have a same shape as each other,
wherein the first concave grooves are recessed from the first surface toward the second surface, and
wherein the second concave grooves are recessed from the second surface toward the first surface.

7. The display device of claim 6, wherein the first concave grooves and the second concave grooves are alternately arranged with each other.

8. The display device of claim 7, wherein each of the first concave grooves and the second concave grooves has a semicircular shape or a polygonal shape.

9. The display device of claim 6, wherein a number of the first concave grooves is greater than a number of the second concave grooves.

10. The display device of claim 9, wherein the number of the first concave grooves is odd.

11. A display device comprising:
a display panel comprising a folding area, a first non-folding area disposed on a first side of the folding area, and a second non-folding area disposed on a second side of the folding area; and
a cover window located on the display panel and having a pattern portion overlapping the folding area,
wherein the pattern portion comprises a plurality of first concave grooves and a plurality of second concave grooves, wherein the plurality of first concave grooves are formed in a first surface of the cover window, and the plurality of second concave grooves are formed in a second surface of the cover window opposite to the first surface and facing the display panel,
wherein each of the plurality of first and second concave grooves comprises an inner wall that extends from the first surface or the second surface of the cover window, a curved surface that extends from the inner wall, and a chamfered surface located adjacent to the inner wall,
wherein an angle formed by the first surface of the cover window and the inner wall of the first concave groove ranges from about 80 degrees to about 89 degrees, and
wherein a radius of curvature at an end of the curved surface of the first concave groove is greater than about 10 μm and less than about 30 μm.

12. The display device of claim 11, wherein a minimum length of the chamfered surface from the inner wall to the first surface of the cover window ranges from about 2 μm to 10 μm.

13. The display device of claim 12, wherein an angle formed by the first surface of the cover window and the chamfered surface is smaller than an angle that is formed by the first surface of the cover window and the inner wall of the first concave groove.

14. The display device of claim 11, wherein the radius of curvature at the end of the curved surface is smaller than the radius of curvature of the curved surface at a boundary between the inner wall and the curved surface.

15. The display device of claim 11, wherein the plurality of first concave grooves and the plurality of second concave grooves have a same shape as each other,
wherein the first concave grooves are recessed from the first surface toward the second surface, and
wherein the second concave grooves are recessed from the second surface toward the first surface.

16. The display device of claim 15, wherein the first concave grooves and the second concave grooves are alternately arranged with each other.

17. The display device of claim 16, wherein a number of the first concave grooves is greater than a number of the second concave grooves.

18. A method for fabricating a display device, the method comprising:
preparing a cover window for protecting a display panel comprising a folding area, a first non-folding area disposed on a first side of the folding area, and a second non-folding area disposed on a second side of the folding area; and
forming a patterned portion in the cover window to overlap with the folding area,
wherein the forming of the patterned portion in the cover window comprises:
forming a plurality of first concave grooves in a first surface of the cover window; and
forming a plurality of second concave grooves in a second surface of the cover window that is opposite to the first surface,
wherein each of the plurality of first and second concave grooves comprises an inner wall that extends from the first surface or the second surface of the cover window and a curved surface that extends from the inner wall,
wherein an angle formed by the first surface of the cover window and the inner wall of the first concave groove ranges from about 80 degrees to about 89 degrees,
wherein a radius of curvature at an end of the curved surface of the first concave groove is greater than about 10 μm and less than about 30 μm, and
wherein the patterned portion has a width in a first direction of the cover window, wherein the width is calculated by a following equation:
L≤(r+T)+1,
wherein r denotes a radius of curvature of the cover window disposed at a position overlapping with the folding area when the display panel is folded, wherein T denotes a thickness of the cover window, and L denotes the width of the patterned portion.

19. The method of claim 18, further comprising:
forming a chamfered surface in each of the first and second concave grooves by chamfering.

20. The method of claim 18, wherein the first and second concave grooves are formed by laser-induced deep etching (LIDE).
